(19) United States
(12) Patent Application Publication
(10) Pub. No.: US 2026/0179678 A1
(43) Pub. Date: Jun. 25, 2026

(54) MEMORY DEVICE SENSE AMPLIFIER WITH BALANCED LOCAL VOLTAGE GENERATION CIRCUITRY

(71) Applicant: Micron Technology, Inc., Boise, ID (US)

(72) Inventors: Jun Tan, Weißenfeld (DE); Christopher John Kawamura, Boise, ID (US)

(21) Appl. No.: 19/365,940

(22) Filed: Oct. 22, 2025

Related U.S. Application Data
(60) Provisional application No. 63/738,102, filed on Dec. 23, 2024.

(51) Int. Cl. G11C 11/4091; G11C 5/14; G11C 11/4074

(52) U.S. Cl. CPC G11C 11/4091; G11C 5/147; G11C 11/4074

(57) ABSTRACT

Systems and methods described herein may include operating balanced local voltage generation circuitry of a single-ended data sense amplifier as part of a data sensing operation. Including balanced local voltage generation circuitry may improve performance of a memory device that includes the single-ended data sense amplifier, as described herein.

### CROSS-REFERENCE TO RELATED APPLICATION

This application claims priority to U.S. Provisional Application No. 63/738,102, filed Dec. 23, 2024, which is hereby incorporated by reference in its entirety.

### BACKGROUND

### Field of the Present Disclosure

Embodiments of the present disclosure relate generally to memory devices. More specifically, embodiments of the present disclosure relate to sense amplifier circuitry of a memory device.

### Description of Related Art

Generally, a computing system may include electronic devices that, in operation, communicate information via electrical signals. For example, a computing system may include a processor communicatively coupled to a memory device, such as a dynamic random-access memory (DRAM) device, a ferroelectric random-access memory (FeRAM) device, another random-access memory (RAM) device, and/or a hybrid device that incorporates more than one type of RAM. In this manner, the processor may communicate with the memory device, for example, to retrieve executable instructions, retrieve data to be processed by the processor, and/or store data output from the processor.

The memory devices utilize sense amplifiers during read operations. Read circuitry of the memory device may use the sense amplifiers to receive low voltage (e.g., low differential) signals and amplify the relatively small voltage differences to enable the memory device to interpret the read data. However, some embodiments of the sense amplifiers consume excess resources (e.g., power and/or area). Furthermore, some sense amplifiers may insufficiently amplify or amplify the low voltages too slowly.

Embodiments of the present disclosure may be directed to one or more of the problems set forth above.

### BRIEF DESCRIPTION OF DRAWINGS

FIG. 1 is a simplified block diagram illustrating certain features of a memory device that includes sense amplifiers in bank control circuitry, in accordance with an embodiment;

FIG. 2 is a block diagram illustrating a portion of the memory device of FIG. 1 that includes a respective sense amplifier coupled to selection circuitry associated with a memory array, in accordance with an embodiment;

FIG. 3 is a circuit diagram of an example single-ended sense amplifier of FIG. 2 that includes a charge sharing-based structure to generate a local reference voltage, in accordance with an embodiment;

FIG. 4 is a diagrammatic representation of ratios between respective transistors of the single-ended sensor amplifier of FIG. 3, in accordance with an embodiment;

FIG. 5 is a timing diagram illustrating respective gate voltages simulated as propagated from the single-ended sense amplifier of FIG. 3 relative to signals illustrated in FIG. 4, in accordance with an embodiment; and

FIG. 6 is an example plot that compares performance, while simulated in different operational conditions, of the single-ended sense amplifier of FIG. 3 to performance of an unbalanced single-ended sense amplifier that excludes the charge sharing-based structure, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Semiconductor devices, such as memory devices, may use signals like data signals, command signals, command address signals, data strobes, and the like when performing or enabling operations. In a memory device, these operations may include read operations, write operations, and refresh operations, among other operations. These operations may be enabled through one or more sense amplifiers of the memory device. Some types of the sense amplifiers consume excess resources (e.g., power and/or area) and/or may insufficiently amplify or amplify the low voltages too slowly.

For example, a single-ended (SE) sense amplifier may generate a local reference voltage based on use a fully-differential (FD) latch stage and an unbalanced differential pair, which may correspond to a global input/output analog data (GIO) input voltage being received at gate of one switch while the local reference voltage is generated based on more than one switch serially connected to each other and a ground voltage. Sense amplifiers that operate based on the FD latch stage and the unbalanced differential pair may experience such excess resource consumption and be slow to operate. In such circuits, a local reference voltage may be compared to global input/output analog data (GIO) input voltage to convert the GIO input voltage to a digital data voltage (e.g., to identify the GIO input voltage as a “1” or a “0”). In some unbalanced differential pairs that generate the local reference voltage, a capacitor may be used in combination with one or more transistors to generate the local reference voltage, however, the capacitor may increase power consumption due to the relatively large amounts of current associated with its operation. Moreover, such circuitry may be unbalanced, which has been found to be more sensitive to process corner changes. Thus, improvements to sense amplifier circuitry and operation may be desired that, for example, enable local reference voltage generation without such capacitor and/or that balance circuitry used to generate the local reference voltage.

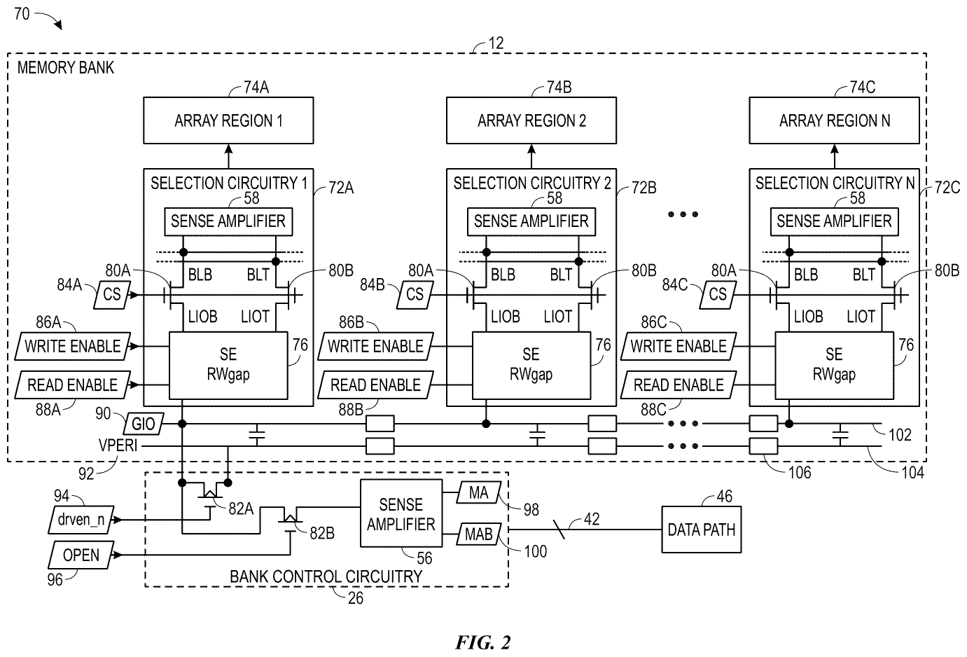

As described herein, balanced local voltage generation circuitry may be included in single-ended sense amplifiers to replace a capacitor and an unbalanced differential pair that may be used to generate the local reference voltage. By removing the capacitor in local reference voltage generation, overall power consumed to perform the generation and/or to operate the memory device may be reduced. By balancing the local reference voltage generation (e.g., equal number of transistors being used to receive the GIO input voltage as generate the local reference voltage), the sense amplifier circuitry may be balanced, and thus experience reduced sensitivity to process corner changes (e.g., as elaborated relative to FIG. 6). By including the balanced local voltage generation circuitry, a variation in trip point may reduce by approximately 80 percent (%) and a settling time may reduce by more than 50% when compared to some sense amplifiers that exclude such balanced local voltage generation circuitry, yielding desirable performance improvements. Furthermore, using the charge sharing-based structure may enable the sense amplifiers to be physically manufactured with relatively smaller footprints when compared to some sense amplifiers that exclude balanced local voltage generation circuitry. The smaller footprint of the sense amplifier circuitry may enable less area of a metal layer being used to provide the sense amplifiers. This and other benefits are described herein relative to sense amplifiers described in FIGS. 2-6.

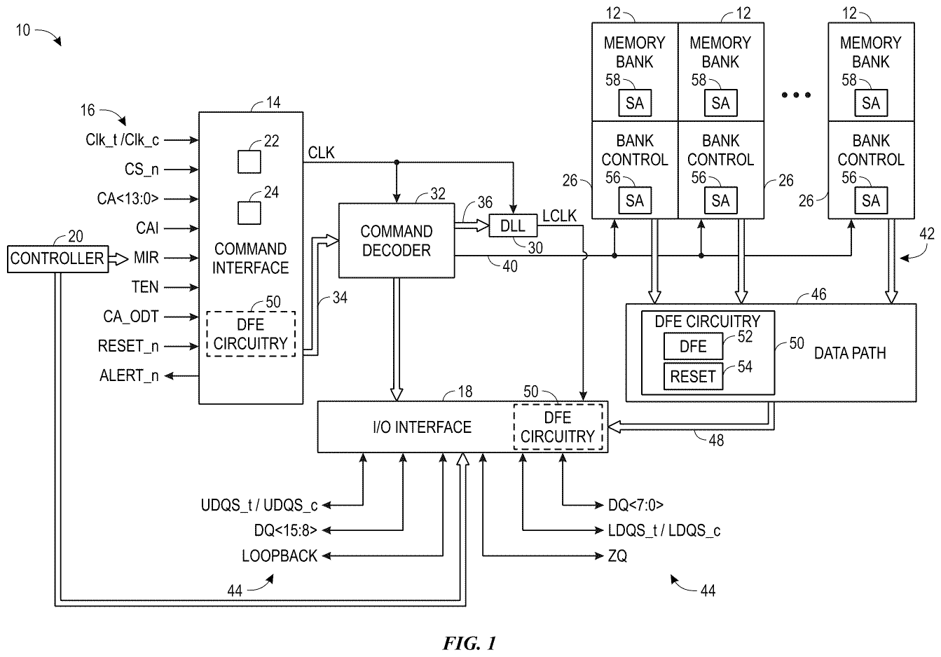

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous double data rate dynamic random access memory (DDR5 SDRAM) device. Various features of DDR5 SDRAM may permit reduced power consumption, more bandwidth, and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMs). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application of the overall system. Furthermore, DDR5 SDRAM configurations are discussed by way of example, but it is understood that various other memory specifications such as past and evolving DDR and low power DDR (LPDDR) configurations have similar functions and may likewise benefit from the circuits and methods described herein. As such depending upon the specific DDR specification, various components of FIG. 1 may be altered to comply with the specification.

The memory device 10 may include a command interface 14 and an input/output (I/O) interface 18. The command interface 14 may receive a number of signals (e.g., signals 16, signals 44) from an external device, such as a controller 20. The controller 20 may include processing circuitry. The controller 20 may be a memory controller. The controller 20 may generate and provide various signals 16, 44 to the memory device 10. The signals 44 may include DQ and/or DQS signals. The controller 20 may communicate with the memory device 10 using the signals 16, 44. Thus, the signals 16, 44 may facilitate the transmission and receipt of data to be written to or read from the memory device 10.

As an example of signals 16, the processor or controller may request a read and/or write operation by providing the corresponding command and an address via the CA bus. A chip select (CS) enable signal (e.g., CS_n signal) may be held high (e.g., logical high, logical high voltage level) by the processor or controller when the command is provided by the processor or controller.

The command interface 14 may include a number of circuits, such as a clock input circuit 22 and a command address input circuit 24, for instance, to permit proper handling of the signals 15. The command interface 14 may receive one or more clock signals from an external device. Generally, double data rate (DDR) memory utilizes a differential pair of system clock signals, referred to as the true clock signal (Clk_t) and the complementary clock signal (Clk_c). The positive clock edge for DDR refers to the point where the rising true clock signal (Clk_t) crosses the falling complementary clock signal (Clk_c), while the negative clock edge indicates that transition of the falling true clock signal (Clk_t) and the rising of the complementary clock signal (Clk_c). Commands (e.g., read command, write command, refresh command) are typically entered on the positive edges of the clock signal and data is transmitted or received on both the positive and negative clock edges.

The clock input circuit 22 may receive the true clock signal (Clk_t) and the complementary clock signal (Clk_c) and may generate an internal clock signal (CLK). The internal clock signal (CLK) may be supplied to an internal clock generator 30, such as a delay locked loop (DLL) circuit. The internal clock generator 30 generates a phase controlled internal locked clock signal (LCLK) based on the received internal clock signal (CLK). The phase controlled internal locked clock signal (LCLK) is supplied to the I/O interface 18, for instance, and is used as a timing signal for determining an output timing of read data.

The internal clock signal (CLK) may also be provided to various other components within the memory device 10 and may be used to generate various additional internal clock signals. For instance, the internal clock signal (CLK) may be provided to a command decoder 32. The command decoder 32 may receive command signals from the command/address (CA) bus 34 and may decode the command signals to provide various internal commands. For instance, the command decoder 32 may provide command signals to the internal clock generator 30 over the bus 36 to coordinate generation of the phase controlled internal locked clock signal (LCLK). The phase controlled internal locked clock signal (LCLK) may be used to clock data through the I/O interface 18, for instance.

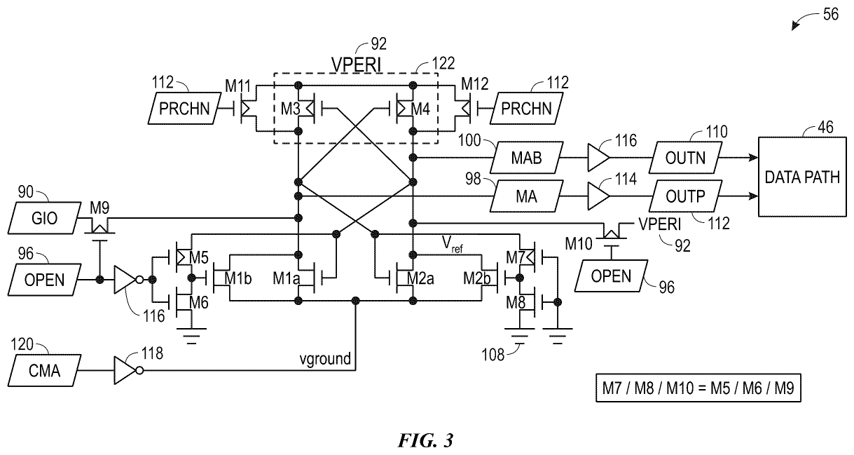

The command decoder 32 may decode commands, such as read commands, write commands, mode-register set commands, activate commands, or the like, and provide access to a particular memory bank 12 corresponding to the command, via the bus 40. The command decoder 32 may include masking circuitry operable to disable propagation of one or more unstable signals, such as masking circuitry illustrated in FIG. 3. The masking circuitry may transmit stable signals via the bus 40 as an output path from the command decoder 32 to downstream circuitry, such as bank control circuitry 26 and/or one or more mode registers of the bank control circuitry 26. In some systems, the command decoder 32 and the masking circuitry are disposed on a same die, such as a die of the memory device 10. In some cases, the controller 20 is disposed on a different die than the command decoder 32.

The memory device 10 may include various other decoders, such as row decoders and column decoders, to facilitate access to the memory banks 12. In one embodiment, each memory bank 12 includes a bank control circuitry 26 which provides the necessary decoding (e.g., row decoder and column decoder), as well as other operations, such as timing control and data control, to facilitate the execution of commands to and from the memory banks 12. Collectively, the memory banks 12 and the bank control circuitry 26 may be referred to as a memory array.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 24. The command address input circuit 24 may be configurable to receive and transmit the commands to provide access to the memory banks 12, through the command decoder 32, for instance. In addition, the command interface 14 may receive a chip select signal (CS_n). The CS_n signal may cause the memory device 10 to process commands on the incoming CA<13:0> bus. Access to specific memory banks 12 within the memory device 10 is encoded on the CA<13:0> bus with the commands.

In addition, the command interface 14 may receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address inverted (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals. This may swap the signals to enable certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may transmit a first command signal and a second command signal at an overlapping time. The transmission may be via the bus 34. The first command signal and/or the second command signal may be associated with address signals. The first command signal may be associated with an odd command count or occurrence of generation and the second command signal may be associated with an even command count or occurrence.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 18. More specifically, the data may be sent to or retrieved from the memory banks 12 over the data path 46, which includes multiple bi-directional data buses. Data I/O signals, generally referred to as DQ signals, are generally transmitted and received in one or more bi-directional data buses. The data path 46 may convert the DQ signals from a serial bus 40 to a parallel bus 42.

For certain memory devices, such as a DDR5 SDRAM memory device, the data I/O signals may be divided into upper and lower bytes. For instance, for a x16 memory device, the data I/O signals may be divided into upper and lower data I/O signals (e.g., DQ<15:8> and DQ<7:0>) corresponding to upper and lower bytes of the data signals, for instance.

To permit higher data rates within the memory device 10, certain memory devices, such as DDR memory devices may utilize data strobe signals, generally referred to as data strobe (DQS) signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 18. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 18. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 18.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description.

DDR5 may enable write operations to be performed consecutively such that data entry is gapless between two consecutive writes. This may enable relatively greater data rates and command processing operations relative to other generations of memory devices and/or architectures. To further support the relatively greater data rates, the memory device 10 may include decision feedback equalizer (DFE) circuitry 50. For example, the DFE circuitry 50 may be included in the data path 46, the I/O interface 18, and/or the command interface 14. The DFE circuitry 50 may use one or more DFEs 52 and an input buffer of a number (e.g., 4) of previous bits (e.g., high or low) to interpret incoming data bits in data IO signals, generally referred to as DQ signals. The DFE circuitry 50 uses the previous levels in the DQ signals to increase accuracy of interpreting incoming bits in the DQ signals. The DFE input buffer depends upon tracking the previous input history on the channel to decide which input tap to use for a next data input. In some cases, the DFE circuitry 50 includes DFE reset circuitry 54 to perform the reset of the DFE 52.

The memory banks 12 and/or bank control circuitry 26 may include sense amplifiers. As part of the desire to increase data rates, sense amplifiers may be desired to be relatively more responsive with faster response times. This may include faster time to locally generate reference voltages. As illustrated, the bank control circuitry 26 includes sense amplifiers 56 and memory banks 12 include sense amplifiers 58, although it should be noted that other combinations of sensing and/or data readout circuitry may be used. The memory device 10 may use push-pull stages (e.g., inverters) in latching circuitry of sense amplifiers 56 and/or sense amplifiers 58 to compare input differential signals and amplify the comparison result to output nodes coupled to downstream circuitry. The memory device 10 may use sense amplifiers 56 during read operations. Read circuitry of the memory device 10 may use the sense amplifiers 56 to receive low voltage (e.g., low differential) signals from the memory cells of the memory banks 12 and may amplify the relatively small voltage differences to enable the memory device 10 to interpret the read data. FIG. 2 elaborates on an example sense amplifier 56 and selection circuitry associated with one or more memory banks 12.

FIG. 2 is a block diagram of a portion 70 of the memory device 10 that includes a sense amplifier 56 and a memory bank 12. Circuitry illustrated in FIG. 2 may be illustrated relative to one memory bank 12 and thus it should be understood that some or each circuitry illustrated in FIG. 2 may be repeated (e.g., tiled) across the memory banks 12 of FIG. 1.

Selection circuitry 72 (selection circuitry 72A, selection circuitry 72B, selection circuitry 72C) may enable respective memory cells to be read or written within array regions 74 (array region 74A, array region 74B, array region 74C) of a respective memory bank 12. Data read may be transmitted via the data path 46 to downstream circuitry. A bus 78 may couple the bank control circuitry 26 to the data path 46. In some cases, the bus 78 may be a parallel bus with two or more respective conductive paths between the bank control circuitry 26 and the data path 46 circuitry, where the bank control circuitry 26 may convert serial data from the array region 74 into parallel data for transmission via the data path 46.

Respective array regions 74 may include word lines, bit lines (BLTs), complimentary bit lines (BLBs), and a number of memory cells arranged at respective intersections of word lines and BLTs. BLTs within the array regions 74 may couple to respective BLTs within respective selection circuitry 72. Additional circuitry, such as sub-word line driver (SWD) regions (not illustrated), may be used to activate word lines of the array region 74 as part of read or write operations. The word lines may be activated based on signals from bank control circuitry 26, such as a row decoder (not illustrated).

A respective selection circuitry 72 may be coupled to a respective array region 74 and may activate respective BLTs and/or BLBs to selectively couple to a memory cell within the coupled array region 74. The memory device 10 include one or more switches 80 (switch 80A, switch 80B) and one or more switches 82. The switches 82 may be p-channel metal-oxide semiconductors (PMOS) transistors. The switches 80 may be n-channel metal-oxide semiconductors (NMOS) transistors. Other transistors or switching circuitry may be used as switches 80 and switches 82, such as to implement control logic similar to that of PMOS transistor switching operations and/or NMOS transistor switching operations. Respective selection circuitry 72 may include respective switches 80 (e.g., pair of switches, pair of NMOS transistors). Respective bank control circuitry 26 (e.g., coupled to each memory bank 12) may include one or more switches 82.

Respective selection circuitry 72 may receive column select (CS) signals 84 (CS signal 84A, CS signal 84B, CS signal 84C). The selection circuitry 72 may receive the CS signal 84 from the bank control circuitry 26 (e.g., from a column decoder of bank control circuitry 26 (not illustrated)). The selection circuitry 72 may couple the BLT to local input/output (LIOT) (or the BLB to complimentary LIO (LIOB)) for a memory access operation (e.g., read operation, write operation, refresh operation). For example, to perform a read operation, the selection circuitry 72 may amplify a signal on the BLT or BLB within the array region 62. In another example, to perform a write operation, a signal (e.g., global input/output (GIO) signal 90 as an input analog data voltage or an input analog voltage) may be transmitted to the selection circuitry 72 from a global input/output (GIO) 90 via conductive path 102 and the LIO (e.g., LIOB or LIOT). It is noted that conductive path 102 and conductive path 104 may include additional circuitry 106 to couple to other memory device 10 components (not illustrated) and/or that enable memory device 10 operations. The additional circuitry 106 may include one or more resistors, one or more capacitors, one or more inductors, one or more buffers, one or more logic gates, or the like.

Between two sense amplifier regions (e.g., local sense amplifiers 58 and data sense amplifier 56), a read/write (RW) gap 68 may control timing and operation of the selection circuitry 72. For example, the RW gap 68 may perform one or more operations to control timing and operation of the selection circuitry 72 as part of a write operation in response to a write enable signal 86 and as part of a read operation in response to a read enable signal 88. The RW gap 68 circuitry may operate based on a voltage, VPERI 92, which corresponds to a system logic high voltage (e.g., “1” voltage level). VPERI 92 may be transmitted to the selection circuitry 72 via a conductive path 104. The RW gap 68 may receive VPERI 92 based on a drive enable signal (drven_n) signal 94, which, when activating a switch 82A, may permit the VPERI 92 to be transmitted to the RW gap 76 and the switch 82B. The sense amplifier 56 may receive analog voltages of data read from the array region 74. The read data may be received via the GIO signal 90 conductive path 102 and the switch 82B when activated by open control (OPEN) signal 96. Based on the read data, the sense amplifier 56 may generate one or more digital data signals (e.g., MA signal 98, complimentary MA (MAB) signal 100) to send to the data path 46 via bus 78 that identify the value of the read data as a digital data value (e.g., an output digital data voltage).

Different types of sense amplifiers may be used as the sense amplifier 56, which may lead to different changes in memory device 10 performance (e.g., slower read out speeds, greater amounts of power consumed during operation). For example, the sense amplifier 56 may be a single-ended data sense amplifier. The single-ended data sense amplifier may include input stage circuitry and latch circuitry to generate the one or more digital data signals (e.g., MA signal 98, MAB signal 100).

The RW gap 68 may be single-ended (SE) type to correspond to the data sense amplifier 56 being single-ended (SE) type. Indeed, the sense amplifier 56 corresponds to a SE sense amplifier as it uses one global input output (GIO) wire with single-ended RW Gap circuitry (SE RWGap) described herein. Using SE RW gap 68 and/or SE sense amplifier 56 may use a smaller footprint and fewer routing resources relative to fully differential (FD) sense amplifiers and/or FD RWGap circuitry.

When the sense amplifier 56 uses an unbalanced differential pair circuitry as input stage circuitry, the sense amplifier 56 may experience relatively greater amounts of process corner change sensitivity than when the input circuitry is balanced. Thus, improvements to sense amplifier circuitry and operation may be desired that, for example, enable local reference voltage generation based on a balanced differential pair circuitry.

FIG. 3 is a circuit diagram of an example single-ended data sense amplifier 56 of FIG. 2 that includes a balanced local voltage generation circuitry to generate a local reference voltage (Vref). The balanced local voltage generation circuitry includes switches M1a, M1b, M2a, M2b. Moreover, the switches M7/M8/M10 may respectively be identical to switches M5/M6/M9. These switches (e.g., M7/M8/M10 and M5/M6/M9) balance a capacitor load coupled upstream (e.g., on the left side) and downstream (e.g., on the right side) of the sense amplifier 56. The switches M5/M6/M10 together may be used to create an internal local reference voltage proportional to VPERI 92 based on the balanced local voltage generation circuitry architecture of FIG. 3. The balanced local voltage generation circuitry may be included in single-ended sense amplifiers (e.g., sense amplifier 56). By balancing the local reference voltage generation (e.g., using switches M2a, M2b being equal in number to switches M1a, M1b and switches M7/M8/M10 being equal in size to switches M5/M6/M9), the sense amplifier 56 may be balanced, and thus experience reduced sensitive to process corner changes (e.g., as elaborated relative to FIG. 6).

To elaborate, the sense amplifier 56 includes multiple switches. Switches M3, M4, M5, M7, M9, M10, M11, and M12, may each be PMOS transistors. Switches M6, M8, M1a, M1b, M2a, M2b may each be NMOS transistors.

Some of the switches (e.g., switch M3, switch M4) form latching circuitry (e.g., a latch 122). A gate terminal of switch M3 is coupled to a drain terminal of switch M4. A gate terminal of switch M4 is coupled to a drain terminal of switch M3.

Switch M11 and switch M12 may receive a precharge control (PRCHN) signal 112 at respective gate terminals. The precharge control (PRCHN) signal 112 activates the switch M11 and the switch M12, which causes VPERI 92 to charge nodes coupling the respective drain terminals of the switches M11 and M3 and of the respective drain terminals of the switches M12 and M4 to the voltage level supplied via VPERI 92. Precharging the nodes propagates VPERI 92 to nodes of source terminals of switches M1a, M1b, M2a, M2b. These nodes store VPERI 92. The OPEN signal 96 may active switch M9 to enable GIO signal 90 to propagate through the circuitry. An inverted OPEN signal 96 may be received at switch M5 and switch M6 (e.g., OPEN signal 96 provided to inverter 116 and output as voltage to gate terminals of switch M5 and switch M6).

When the GIO signal 90 is received, while the OPEN signal 96 is received to permit propagation, the voltage value of the GIO signal 90 propagates to the node coupling the drain terminals of switches M11 and M3. Through this node, the voltage value of the GIO signal 90 propagates to the drain terminal of switch M11, the drain terminal of switch M3, a gate terminal of switch M4, as MA signal 98 to buffer 114, to source terminal of switch M1a, to source terminal of switch M1b, to a gate terminal of switch M2a, to a source terminal of switch M7. A gate terminal of switch M7 is coupled to a gate terminal of switch M8 and to ground. A drain terminal of switch M7 is coupled to a source terminal of switch M8. The source terminals of switches M2a and M2b are coupled to the drain terminal of switch M4 and a source terminal of the switch M10, where these couplings may propagate a generated local reference voltage (Vref), as discussed herein. The drain terminal of switch M10 is coupled to a voltage source of VPERI 92. The gate terminal of switch M10 also may receive the OPEN signal 96. The OPEN signal 96 may also be transmitted to a gate terminal of switch M9, to gate terminals of switch M5 and of switch M6 via inverter 116. A drain terminal of switch M5 couples to a source terminal of switch M6 and a gate of switch M1b. A drain terminal of M6 couples to the ground. The ground may be provided as a hardware, system-wide ground. In some cases, a CMA signal 120 may be received at inverter 118 (e.g., inverting buffer circuitry) to provide a logic low voltage as a ground voltage (vground). Drain terminals of switches M1a, M1b, M2a, M1b may each couple together and to the ground.

The switches M11 and M6 may be operated as two switches, which may short the gate of switch M1a to either VSS (e.g., the ground) or the gate of switch M1b. The switches M11 and M6 are controlled by the inverted OPEN signal 96 (e.g., output from inverter 118). When the OPEN signal 96 is high (e.g., high logic voltage level), the gate of switch M1a is shorted to the gate of switch M1b, while the gate voltage of switch M1a is VSS responsive to the OPEN signal 96 having a low logic voltage level. The switch M9 may conduct the input GIO signal 90 to the sense amplifier 56 when OPEN signal 96 having a low logic voltage level. Switch M9 in FIG. 3 may correspond to switch 82B in FIG. 2. The switch M9 may be considered an input switch. The switches M7, M8, M10 may be identical (respectively) to switches M11, M6, M9, as these switches balance a capacitive load between different portions of the sense amplifier 56 circuit. The switches M11, M6, M10 may create the internal local reference voltage (Vref) as proportional to VPERI 92.

The generated internal local reference voltage (Vref) may be applied as output MAB 100 as a precharged reference voltage. While a CMA signal 120 is received as a logic high voltage level (e.g., is switched on), the sense amplifier 56 performs the data sense operation based on two inputs—a first input as the GIO signal 90 and a second input as the generated local reference voltage (Vref).

The sense amplifier 56 may output logic high data to the data path 46 when the GIO signal 90 propagated is greater than the local reference voltage (Vref). The sense amplifier 56 may output logic low data when the GIO signal 90 propagated is less than the local reference voltage (Vref). The local reference voltage (Vref) corresponds to a voltage value between the logic low voltage and the logic high voltage, such that it can act as a suitable comparison value to identify whether incoming analog data corresponds to a digital high bit “1” or a digital low bit “0.”

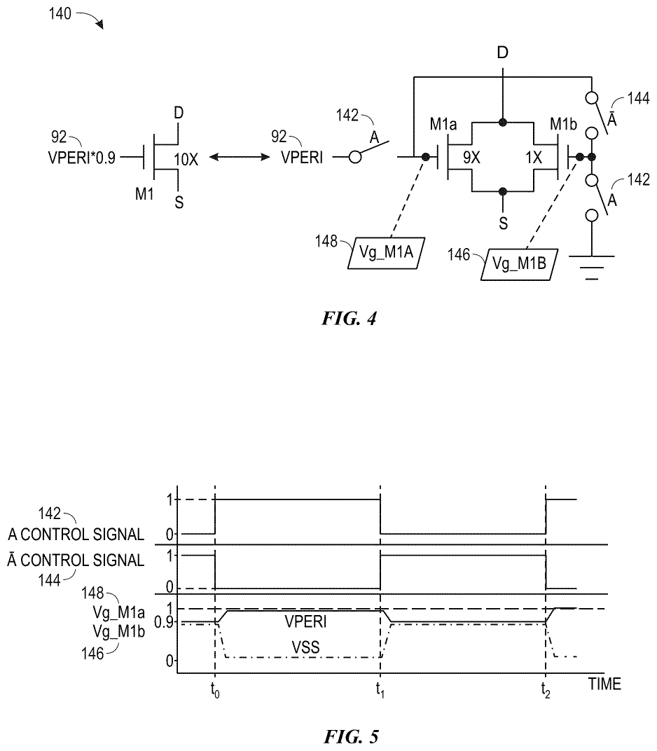

The respective sizes of the switches M2a and M2b set the voltage value of the reference voltage (Vref) node. The combined size switches M2a and M2b are balanced by the combined size of switches M1a and M1b. The two pairs of switches M2a and M2b relative to M1a and M1b may be equal or substantially equal such that differences in size are negligible in generation of the Vref and performance. The switch sizes may change based on a number of fingers the respective switch is manufactured with, where the finger may refer to the electromechanical underlying structure of the switch, such as when the switch is a NMOS or PMOS or other suitable transistor circuitry. The ratio between switches M2a and M2b (and thus also in switches M1a and M1b) may be nine-to-one (9:1), which sets the Vref at 90% of VPERI 92. The size of switch M2a may be a multiple of the size of switch M2b (e.g., 9×, 9 times). The size of switch M1a may be a multiple of the size of switch M2b (e.g., 9×, 9 times). The size of switch M1a may be a multiple of the size of switch M1b (e.g., 9×, 9 times). The size of switch M2a may be a multiple of the size of switch M1b (e.g., 9×, 9 times). As an example, the switch M2a may have 9 times the fingers (e.g., nine fingers), or be 9 times the size (e.g., width), of Switch M2b (e.g., ratio of 9:1), which may have one finger, as is elaborated on relative to at least FIG. 4.

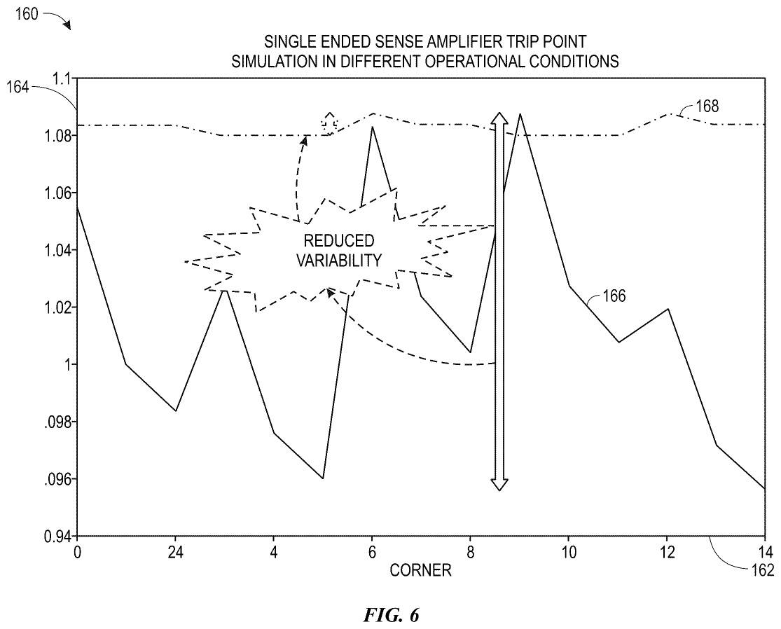

FIG. 4 is a diagrammatic representation of circuitry 140 of respective transistors 80 of the single-ended sense amplifier 56. FIG. 5 is a timing diagram illustrating respective gate voltages simulated as propagated from the single-ended sense amplifier 56 relative to signals illustrated in and described relative to FIG. 4. For ease of discussion, FIGS. 4-5 are described together herein to further elaborate on operation of pair of switches M1a/M1b and pair of switches M2a/M2b relative to described operations of the switch M1a and the switch M1b.

The switch M1b and the switch M1a may be modeled as switch M1 as an NMOS transistor with ten fingers. The switch M1a in FIG. 4 has nine of the ten fingers. The switch M1b in FIG. 4 has one of the ten fingers. Two operating phrases may be used to operate the circuitry 140.

In a precharge phase (e.g., precharging operations performed between time, t0, and time, t1), control signal 142 is supplied to switches A to activate the switches A. While control signal 144 (the inverse of control signal 142) is supplied to switch A to deactivate the switch A. The control signal 142 may correspond to the precharge control (PRCHN) signal 112 and the control signal 144 may correspond to the OPEN signal 96. During the precharge phase, the M1a is biased by VPERI 92, while switch M1b is biased by VSS. This may cause gate terminal voltage of switch M1a (“Vg_M1a”) 146 to increase toward a VPERI 92 voltage level. This may cause gate terminal voltage of switch M1b (“Vg_M1b”) 148 to decrease toward a ground voltage level.

During a second phase, a sensing phase (e.g., sensing or readout operations performed between time, t1, and time, t2), control signal 142 may be provided to switches A to deactivate the switches (e.g., control signal 142 may equal a logic low voltage level). The inverse of the control signal 142 (e.g., control signal 144) may be provided to switch Ā to activate the switch Ā. The gates of switch M1a and switch M1b are shorted together while the switch A is deactivated, creating operationally a single transistor, switch M1. The charges on the gate of switch M1 may be shared together, causing the voltage on the shared gate of switch M1 to equal approximately 0.9*VPERI (e.g., 90% of the voltage value of VPERI 92 or a negligible amount from that value). This may couple the gate of switches M1a and M1b to the latch 122, which provides the local reference voltage (Vref) as MAB signal 100. During the second phase, the gate terminal voltage of switch M1a (“Vg_M1a”) 146 may decrease toward the ground voltage level and the gate terminal voltage of switch M1b (“Vg_M1b”) 148 may increase toward the VPERI 92 voltage level.

After time, t2, precharging and sensing operations may repeat to perform subsequent sense amplifier 56 sensing operations for subsequently received analog data as the GIO signal 90.

It is noted that in an actual implementation, the local reference voltage generated may be approximately 90% of a voltage value of VPERI 92 (e.g., between 89-91% of VPERI 92, 85-95% of VPERI 92, or the like) without being exactly 90% of the voltage value of VPERI 92. This may be due to one or more capacitive loads associated with the sense amplifier 56, material characteristics of die or circuitry of the sense amplifier 56, loads downstream or circuitry upstream from the sense amplifier 56, or the like. In some cases, some of the charge of switch 80E may be lost in the transition between the precharge phase and sensing phase, and thus approximately 90% of VPERI 92 may be generated. However, this may be compensated in some cases through a higher load being coupled to switches M2a, M2b, M8, M4 and an input capacitance of the inverters 118 may reach a greater voltage than 0.9*VPERI and be balanced out by the charge of the switch 80E being lost in the transition between the precharge phase and the sensing phase.

FIG. 6 is an example plot 160 that compares performance of the single-ended sense amplifier of FIG. 3 to performance a single-ended sense amplifier that excludes the charge sharing-based structure while simulated in different operational conditions. The performance may have been tested in a simulation on a test bench that coupled the sense amplifier 56 of FIG. 3 downstream from SE RWgap 76 in the memory bank 12, where the modeling included coupling through a model of paths receiving GIO 90 and VPERI 92 of FIG. 2. Indeed, plot 160 illustrates simulation results comparing two respective single ended sense amplifier trip points (e.g., trip voltage on Y-axis 164) sensed over different operational conditions (e.g., process, voltage, temperature corners on X-axis 162). The sense amplifiers simulated include the sense amplifier 56 described herein (corresponding to line 168) relative to other sense amplifier circuitry (corresponding to line 166), such as circuitry that include unbalanced circuitry to generate a reference voltage and/or a capacitor to generate the reference voltage. As emphasized through the diagrammatic representation overlaid on plot 160, the sense amplifier 56 described herein (corresponding to line 168) experienced reduced variability in trip point relative to other unbalanced, capacitor-based sense amplifiers, which emphasizes technical improvement that may be realized through using systems and methods described herein.

Technical improvements of the present disclosure may be realized through including balanced local voltage generation circuitry in single-ended sense amplifiers. Such balanced local voltage generation circuitry may be balanced and may replace a capacitor and an unbalanced differential pair to generate the local reference voltage. By including the balanced local voltage generation circuitry, nodes of a latch stage may be directly coupled to a ground, which may cause relatively faster sensing outputs relative to unbalanced generation circuitry. Moreover, by removing the capacitor, the memory device may consume lower amounts of resources during operations (e.g., power consumption). By using an equal number of transistors to receive the GIO input voltage as to generate the local reference voltage, the sense amplifier circuitry may be balanced. By balancing the sense amplifier circuitry, the sense amplifier circuitry may be less sensitive to process corner or other operational changes (e.g., as elaborated relative to FIG. 6). Furthermore, using the balanced local voltage generation circuitry-based structure may enable the sense amplifiers to be physically manufactured with relatively smaller footprints when compared to some sense amplifiers that use unbalanced circuitry, which may be desirable in continual attempts to make devices small for consumers and/or to increase computing capability of devices by increasing density of components in devices.

Although the foregoing discusses various logic low and/or logic high signal polarities, at least some of these polarities may be inverted in some embodiments. Furthermore, in some systems, logic gates as discussed herein may be replaced with one or more logic gates, such as inverters, AND gates, not-AND (NAND) gates, OR gates, not-OR (NOR) gates, or other types of combinational logic.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An apparatus, comprising:
memory bank control circuitry, wherein the memory bank control circuitry is configured to generate digital data based on a sense amplifier receiving a global input/output analog data (GIO) input voltage, wherein the sense amplifier comprises balanced local voltage generation circuitry; and
a data path coupled to the memory bank control circuitry, wherein the data path is configured to transmit the digital data to downstream circuitry.

2. The apparatus of claim 1, wherein the sense amplifier comprises a latch configured to couple to ground through the balanced local voltage generation circuitry.

3. The apparatus of claim 2, wherein the balanced local voltage generation circuitry comprises:
a first node at a coupling of a source terminal of a first switch and of a source terminal of a second switch, wherein the balanced local voltage generator is configured to receive the GIO input voltage via the first node;
a second node at a coupling of a source terminal of a third switch and of a source terminal of a fourth switch, wherein the balanced local voltage generator is configured to generate the local reference voltage via the second node; and
a third node at a coupling of a drain terminal of the first switch, a drain terminal of the second switch, a drain terminal of the third switch, and a drain terminal of a fourth switch, wherein the latch is configured to couple to ground through the third node of the balanced local voltage generation circuitry based on the first switch, the second switch, the third switch, and the fourth switch being activated.

4. The apparatus of claim 3, wherein the sense amplifier is configured to generate the digital data based on a latch receiving the local reference voltage and the GIO input voltage.

5. The apparatus of claim 1, wherein the balanced local voltage generation circuitry comprises a first transistor with one finger, a second transistor with one finger, a third transistor with nine fingers, and a fourth transistor with nine fingers.

6. The apparatus of claim 5, wherein the balanced local voltage generation circuitry is configured to generate a local reference voltage as a voltage less than a logic high voltage level (VPERI) based on a ratio between a number of fingers of the first transistor and a number of fingers of the third transistor.

7. The apparatus of claim 1, wherein the balanced local voltage generation circuitry is configured to operate based on receiving the GIO input voltage in response to an open control signal activating an upstream transistor.

8. The system of claim 7, wherein the balanced local voltage generation circuitry is configured to couple a latch of the sense amplifier to ground in response to the open control signal.

9. A circuit, comprising:
a first input switch to receive a global input/output analog data (GIO) input voltage;
a second input switch to receive a system logic high voltage;
balanced local voltage generation circuitry comprising:
a first switch and a second switch coupled to each other through source terminals and to the first input switch through a drain terminal; and
a third switch and a fourth switch coupled to each other through source terminals and to the second input switch through a source terminal; and
a latch coupled to the first input switch and the balanced local voltage generation circuitry, wherein the latch is configured to generate an output digital data voltage based on comparing the GIO input voltage to a local reference voltage generated based on the third switch and the fourth switch.

10. The circuit of claim 9, comprising a data path coupled to the latch, the data path configured to transmit the output digital data voltage to downstream circuitry.

11. The circuit of claim 9, wherein the local voltage generation circuitry is configured to generate the local reference voltage on a node coupling the source terminal of the third switch to the source terminal of the fourth switch.

12. The circuit of claim 9, wherein a first set of switches comprises the first input switch, a fifth switch, and a sixth switch, wherein a second set of switches comprises the first input switch, a seventh switch, and an eighth switch, and wherein the first set of switches are collectively a same size as a collective size of the second set of switches.

13. The circuit of claim 12, wherein the first input switch and the second input switch are both configured to operate responsive to an open control signal, wherein an inverted open control signal is sent to gate terminal of the first set of switches.

14. The circuit of claim 9, wherein the first switch has a first width, wherein the second switch as a second width that is a multiple of the first width, wherein the third switch has the second width, and wherein the fourth switch has the first width.

15. The circuit of claim 9, wherein the third switch and the fourth switch are configured to generate the local reference voltage as a voltage less than a logic high voltage level (VPERI) based on a ratio between the first width and the second width.

16. The circuit of claim 9, wherein the first switch and the second switch are configured to receive the GIO input voltage, and wherein the third switch and the fourth switch are configured to generate the local reference voltage using a same number of transistors as the first switch and the second switch.

17. The circuit of claim 9, wherein, during a precharge operation, the third switch and the fourth switch have respective source terminals loaded with the system logic high voltage.

18. The circuit of claim 17, wherein, during a sensing operation, the second input switch receives an open control signal at a gate terminal and operates, respective to the open control signal, to transmit the system logic high voltage to gate terminals of the third switch and the fourth switch, causing transmission of the local reference voltage.

19. A method comprising:
generating a precharge control signal to operate balanced local voltage generation circuitry of a single-ended data sense amplifier to precharge one or more nodes of a single-ended data sense amplifier and of the balanced local voltage generation circuitry; and
generating an open control signal to operate the single-ended data sense amplifier to perform a sensing operation.

20. The method of claim 19, wherein performing the sensing operation comprises:
transmitting a global input/output analog data (GIO) input voltage to a latch of the single-ended data sense amplifier;
operating, based on the generated open control signal, the balanced local voltage generation circuitry to provide a local reference voltage to the latch of the single-ended data sense amplifier; and
reading, from a data path, an output digital data voltage from the latch based on the GIO input voltage being compared to the local reference voltage.
